(19) United States
(12) Patent Application Publication
(10) Pub. No.: US 2021/0208458 A1
(43) Pub. Date: Jul. 8, 2021

(54) ARRAY SUBSTRATE, MANUFACTURING METHOD THEREOF, AND DISPLAY DEVICE

(71) Applicants: BOE TECHNOLOGY GROUP CO., LTD., Beijing (CN); Chongqing BOE Optoelectronics Technology Co., Ltd., Chongqing (CN)

(72) Inventors: Haoxiang FAN, Beijing (CN); Zhe LI, Beijing (CN); Peng LI, Beijing (CN); Xiaoji LI, Beijing (CN); Keke GU, Beijing (CN); Wenliang LIU, Beijing (CN); Peng QIN, Beijing (CN); Junhong LU, Beijing (CN); Wei ZHU, Beijing (CN)

(21) Appl. No.: 16/082,247

(22) PCT Filed: Feb. 8, 2018
(86) PCT No.: PCT/CN2018/075833

§ 371 Date: Sep. 4, 2018

(30) Foreign Application Priority Data
Jul. 28, 2017 (CN) 201710637585.1

(51) Int. Cl. G02F 1/1343; H01L 27/12

(52) U.S. Cl. CPC G02F 1/134372; G02F 1/13439; G02F 1/134345; G02F 1/134363; H01L 27/1259

(57) ABSTRACT

An array substrate includes a slit electrode and a planar electrode disposed in each of sub-pixels on a base substrate. The planar electrode is located on a side of the slit electrode close to the base substrate, and the slit electrode includes a plurality of strip sub-electrodes. In each of the sub-pixels, an insulating layer is disposed between the slit electrode and the planar electrode, and a surface of the insulating layer facing away from the base substrate is provided with a groove at a position between at least one set of adjacent strip sub-electrodes in the plurality of strip sub-electrodes.

### CROSS-REFERENCE TO RELATED APPLICATION

This application is a national phase entry under 35 USC 371 of International Patent Application No. PCT/CN2018/075833 filed on Feb. 8, 2018, which claims priority to Chinese Patent Application No. 201710637585.1, filed on Jul. 28, 2017 to Chinese Patent Office, titled “ARRAY SUBSTRATE, MANUFACTURING METHOD THEREOF, AND DISPLAY DEVICE”, which are incorporated herein by reference in their entirety.

### TECHNICAL FIELD

The present disclosure relates to the field of display technologies, and more particularly to an array substrate, a manufacturing method thereof and a display device.

### BACKGROUND

As a flat panel display device, a TFT-LCD (Thin Film Transistor Liquid Crystal Display) is increasingly used in the field of high performance display due to its small size, low power consumption, no radiation, and relatively low manufacturing cost.

The existing liquid crystal display device has various display modes, such as TN (Twist Nematic) type, ADS (Advanced-Super Dimensional Switching), and IPS (In Plane Switch) type, etc. The ADS type display mode is widely used in the field of television display due to its wide viewing angle.

### SUMMARY

A first aspect of the disclosure provides an array substrate. The array substrate includes a slit electrode and a planar electrode disposed in each of sub-pixels on a base substrate. The planar electrode is disposed on a side of the slit electrode close to the base substrate, and the slit electrode includes a plurality of strip sub-electrodes. In each of the sub-pixels, an insulating layer is disposed between the slit electrode and the planar electrode, and a surface of the insulating layer facing away from the base substrate is provided with a groove at a position between at least one set of adjacent strip sub-electrodes in the plurality of strip sub-electrodes.

Optionally, the surface of the insulating layer facing away from the base substrate is provided with the groove at a position between every two adjacent strip sub-electrodes in the plurality of strip sub-electrodes.

Optionally, the surface of the insulating layer facing away from the base substrate is integrally recessed in a defined region between every two adjacent strip sub-electrodes in the plurality of strip sub-electrodes to form the groove.

Optionally, the array substrate further includes a dielectric layer located between the base substrate and the planar electrode, and the dielectric layer includes a raised portion corresponding to a position of the groove.

Optionally, the insulating layer includes a gate insulating layer and a protective layer disposed in sequence, and the gate insulating layer is located on a side of the protective layer close to the base substrate. In each of the sub-pixels, the gate insulating layer is a planar structure, and the protective layer has a hollow portion therein. The hollow portion and a portion of the gate insulating layer corresponding to the hollow portion constitute the groove.

Optionally, the insulating layer includes a gate insulating layer and a protective layer disposed in sequence, and the gate insulating layer is located on a side of the protective layer close to the base substrate. In each of the sub-pixels, the gate insulating layer is a planar structure, and the groove is located in the protective layer.

Optionally, the protective layer includes a first protective layer and a second protective layer, which are disposed on the gate insulating layer in sequence, the second protective layer has a hollow portion therein, and the hollow portion and a portion of the first protective layer corresponding to the hollow portion constitute the groove.

Optionally, a depth of the groove ranges from 0.4 μm to 0.7 μm.

Optionally, a depth of the groove ranges from 0.4 μm to 0.7 μm, and a distance from a bottom of the groove to a surface of the gate insulating layer facing away from the base substrate ranges from 0.15 μm to 0.25 μm.

Another aspect of the disclosure further provides a display device. The display device includes the above-mentioned array substrate.

Yet another aspect of the disclosure further provides a manufacturing method of the array substrate. The manufacturing method includes: forming a planar electrode at least in a region of each of sub-pixels to be formed on the base substrate; forming an insulating layer on the planar electrode, and forming a groove in a surface of the insulating layer by a patterning process at a position between at least one set of adjacent strip sub-electrodes in a plurality of adjacent strip sub-electrodes of the slit electrode to be formed; and forming a slit electrode on the insulating layer that has the groove in its surface.

Optionally, forming the insulating layer on the planar electrode and forming the groove in the surface of the insulating layer by the patterning process at the position between at least one set of adjacent strip sub-electrodes of the slit electrode to be formed specifically includes: forming a gate insulating layer on the planar electrode; forming a protective layer on the gate insulating layer, and forming a groove in a surface of the protective layer by a patterning process at a position between the at least one set of adjacent strip sub-electrodes in the plurality of adjacent strip sub-electrodes of the slit electrode to be formed; or forming a protective layer on the gate insulating layer, and forming a hollow portion in the surface of the protective layer by a patterning process at a position between the at least one set of adjacent strip sub-electrodes in the plurality of adjacent strip sub-electrodes of the slit electrode to be formed. The hollow portion and a portion of the gate insulating layer corresponding to the hollow portion constitute the groove.

Optionally, forming the insulating layer on the planar electrode, and forming the groove in the surface of the insulating layer by the patterning process at the position between at least one set of adjacent strip sub-electrodes in a plurality of adjacent strip sub-electrodes of the slit electrode to be formed, specifically includes: forming a gate insulating layer on the planar electrode; forming a first protective layer on the gate insulating layer; and forming a second protective layer on the first protective layer, and forming a hollow portion in a surface of the second protective layer by a patterning process at a position between the at least one set of adjacent strip sub-electrodes in the plurality of adjacent strip sub-electrodes of the slit electrode to be formed. The hollow portion and a portion of the first protective layer corresponding to the hollow portion constitute the groove.

Optionally, forming the insulating layer on the planar electrode and forming the groove in the surface of the insulating layer by the patterning process at the position between at least one set of adjacent strip sub-electrodes in the plurality of adjacent strip sub-electrodes of the slit electrode to be formed specifically includes: forming an insulating layer on the planar electrode and forming a groove in the surface of the insulating layer by a patterning process at a position between every two adjacent strip sub-electrodes in the plurality of adjacent strip sub-electrodes of the slit electrode to be formed.

### BRIEF DESCRIPTION OF THE DRAWINGS

In order to describe technical solutions in embodiments of the present disclosure more clearly, the accompanying drawings to be used in the description of embodiments will be introduced briefly. Obviously, the accompanying drawings to be described below are merely some embodiments of the present disclosure, and a person of ordinary skill in the art can obtain other drawings according to those drawings without paying any creative effort.

FIG. 1 is a schematic structure diagram of an illustrative ADS type liquid crystal display panel;

FIG. 2 is a schematic plane structure diagram of an ADS type array substrate provided by some embodiments of the present disclosure;

FIG. 3a is a schematic sectional structure diagram of FIG. 2 along a position O-O′;

FIG. 3b is a schematic sectional structure diagram of another ADS type array substrate provided by some embodiments of the present disclosure;

FIG. 4 is a schematic sectional structure diagram of a further ADS type array substrate provided by some embodiments of the present disclosure;

FIG. 5 is a schematic sectional structure diagram of yet another ADS type array substrate provided by some embodiments of the present disclosure;

FIG. 6 is a schematic structure diagram of an ADS type display device provided by some embodiments of the present disclosure;

FIG. 7 is a graph showing transmittances and voltages of ADS type display devices provided by some embodiments of the present disclosure and the embodiments shown in FIG. 1;

FIG. 8 is a graph showing transmittances and light wavelengths of ADS type display devices provided by some embodiments of the present disclosure and the embodiments shown in FIGS. 1; and

FIG. 9 is a flowchart of a manufacturing method of an ADS type array substrate provided by some embodiments of the present disclosure.

### DETAILED DESCRIPTION

Technical solutions in embodiments of the present disclosure will be described clearly and completely below with reference to the accompanying drawings in the embodiments of the present disclosure. Apparently, the embodiments to be described are merely some but not all of embodiments of the present disclosure. On the basis of the embodiments of the present disclosure, all other embodiments obtained by a person of ordinary skill in the art shall be included in the protection scope of the present disclosure without paying any creative effort.

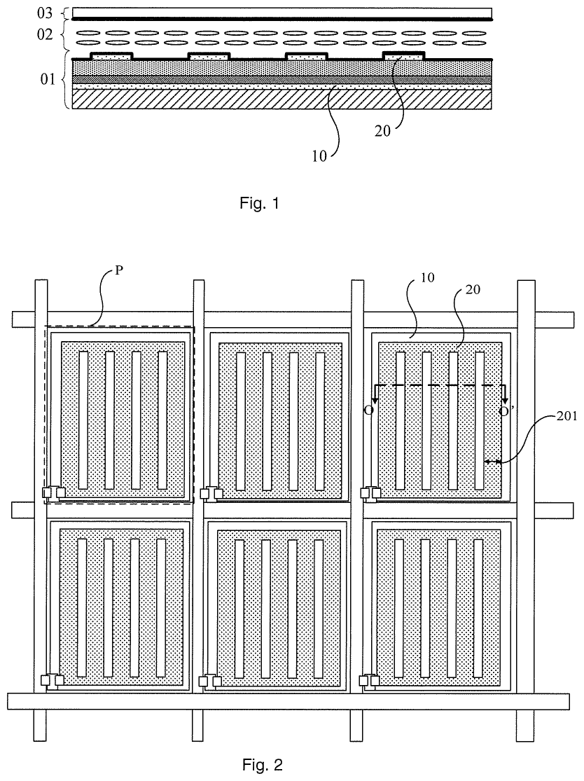

FIG. 1 shows an example of a liquid crystal display panel of an ADS mode. The liquid crystal display panel of the ADS mode includes an array substrate 01, a color film substrate 03, and a liquid crystal layer 02 located between the array substrate 01 and the color film substrate 03. The array substrate 01 includes a planar electrode 10 and slit electrodes 20, which are used to drive the liquid crystal layer 02. The slit electrodes 20 are closer to the liquid crystal layer 02 than the planar electrode 10. In the display panel of the ADS mode, a directly facing area between the planar electrode and each slit electrode is relatively large, and a storage capacitance between the planar electrode and each slit electrode is significantly increased relative to a required capacitance for the normal display, which may have an adverse effect on the display.

A method of increasing a distance between the planar electrode and the slit electrode (that is, increasing a thickness of an insulating layer between the planar electrode and the slit electrode) is used to reduce the storage capacitance between the planar electrode and the slit electrode. However, while the method is used to reduce the storage capacitance, the utilization of electric field is reduced, and thus an operating voltage Vop of a display device is increased. In other words, by adjusting the distance between the planar electrode and the slit electrode, the operating voltage Vop is increased while the storage capacitance is reduced; or, the storage capacitance is increased while the operating voltage Vop is reduced.

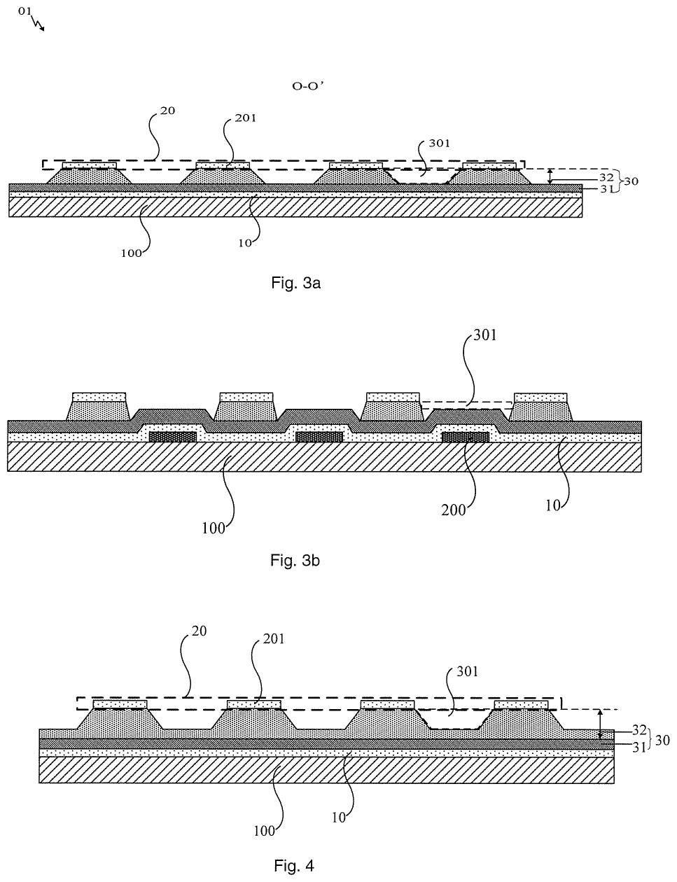

FIG. 2 shows an example of an array substrate provided by some embodiments of the present disclosure. The array substrate 01 includes a slit electrode 20 and a planar electrode 10 that are disposed in each of sub-pixels P on a base substrate 100 (not shown in FIG. 2, see FIG. 3a). As shown in FIG. 3a (a schematic sectional structure diagram of FIG. 2 along a position O-O′), the planar electrode 10 is located at a side of the slit electrode 20 close to the base substrate 100, and the slit electrode 20 includes a plurality of strip sub-electrodes 201, that is, the array substrate 01 is of an ADS type. In each of the sub-pixels P, an insulating layer 30 is disposed between the slit electrode 20 and the planar electrode 10, and a surface of the insulating layer 30 facing away from the base substrate 100 is provided with a groove 301 between at least one set of adjacent strip sub-electrodes in the plurality of strip sub-electrodes 201.

Here, it will be noted that, firstly, as for the above-mentioned planar electrode 10, it means that this electrode has an entire structure, and there is no gap or hollow portion in the electrode. Besides, the planar electrode can be flat or non-flat, depending on the shape of the bearing surface on which the planar electrode is placed.

Secondly, as for the above-mentioned groove 301, it will be understood that the groove means a structure having a bottom surface, that is, a portion of the insulating layer between the slit electrode 20 and the planar electrode 10 is left at a position of a bottom surface of a corresponding groove 301.

Thirdly, the slit electrode 20 can be a ladder-shaped slit electrode shown in FIG. 2, or a comb slit electrode, or a slit electrode of other shape, which is not limited in the present disclosure.

In summary, since in the insulating layer 30 between the slit electrode 20 and the planar electrode 10, the groove 301 is provided at a position between the adjacent strip sub-electrodes 201 of the plurality of strip sub-electrodes 201, the thickness of the portion of the insulating layer 30 located between the adjacent strip sub-electrodes 201 of the plurality of strip sub-electrodes 201 is reduced. In this way, compared to the solution in which a thickness of an entire insulating layer 30 is uniform in the illustrative embodiments shown in FIG. 1, in the embodiments shown in FIG. 3a of the present disclosure, it is possible to ensure that the directly facing area between the slit electrode 20 and the planar electrode 10 is constant, that is, the storage capacitance is not increased, and based on this, by reducing the thickness of the portion of the insulating layer 30 located between two adjacent strip sub-electrodes 201, a weakening effect of the insulating layer 30 on the electric field formed between the slit electrode 20 and the planar electrode 10 is reduced, thereby improving the utilization of the electric field between the planar electrode 10 and the slit electrode 20 and further reducing the operating voltage Vop. Therefore, as for a display device including the array substrate, power consumption may be reduced.

Of course, in order to further improve the utilization of the electric field and reduce the operating voltage Vop, as shown in FIG. 3b, the array substrate 01 further includes a dielectric layer located between the base substrate 100 and the planar electrode 10, and the dielectric layer includes a raised portion 200 corresponding to the position of the groove 301. In this way, the planar electrode 10 is raised at the position of the groove 301 through the raised portion. Here, the planar electrode 10 is of a non-flat structure. At the position of the groove 301, the distance between the planar electrode 10 and the slit electrode 20 is reduced, thereby improving the utilization of the electric field and reducing the operating voltage Vop. Of course, in view of a manufacturing process, the raised portion 200 can be processed by a single manufacturing process along with gate lines in the array substrate, that is, the raised portion 200 is disposed in the same layer as the gate lines and they are made from the same material.

For illustrative purposes, the disclosure is further explained in the following embodiments by taking the above-mentioned raised portion 200 being not provided, i.e., the planar electrode 10 being a flat structure as an example.

Optionally, in order to further reduce the weakening effect of the insulating layer 30 on the electric field formed between the slit electrode 20 and the planar electrode 10, as shown in FIG. 3a, a surface of the insulating layer 30 facing away from the base substrate 100 is provided with the groove 301 between every two adjacent strip sub-electrodes 201. In other words, in each of the sub-pixels P, the groove 301 is disposed between any two adjacent strip sub-electrodes 201 of the plurality of strip sub-electrodes 201, so that the weakening effect of the insulating layer 30 on the electric field formed between the slit electrode 20 and the planar electrode 10 is reduced as a whole. In other words, the utilization of the electric field between the planar electrode 10 and the slit electrode 20 is comprehensively improved, thereby effectively reducing the operating voltage Vop.

Optionally, in order to furthest reduce the weakening effect of the insulating layer 30 on the electric field formed between the slit electrode 20 and the planar electrode 10, as shown in FIG. 3a, the surface of the insulating layer 30 facing away from the base substrate 100 is integrally recessed in a defined region between every two adjacent strip sub-electrodes of the plurality of strip sub-electrodes 201 to form the groove 301. In other words, two edges of the opening of the groove 301 in a width direction of each of the plurality of sub-electrodes 201 overlap with two adjacent sides of two strip sub-electrodes 201 in the plurality of sub-electrodes 201 adjacent to the groove 301 in the width direction. In other words, the insulating layer 30 has a strip-like raised structure under a corresponding strip sub-electrode 201 in the plurality of strip sub-electrodes 201, and the surfaces of raised structures have the same cycle as the strip sub-electrodes and each surface has the same center as a corresponding strip sub-electrode. Orthographic projections of the surface of the raised structure and the strip sub-electrode on the base substrate are coincident. In this way, the weakening effect of the insulating layer 30 on the electric field formed between the slit electrode 20 and the planar electrode 10 is minimized, and thus the utilization of the electric field between the planar electrode 10 and the slit electrode 20 is improved.

It will be noted that, as can be seen from FIG. 3a, a section of a portion of the insulating layer 30 under a corresponding strip sub-electrode 201 of the plurality of strip sub-electrodes 201 has a trapezoidal structure. A width of a surface of the portion touching the corresponding strip sub-electrode 201 of the plurality of strip sub-electrodes 201 is small, while a width of the portion is gradually increased in a direction away from the corresponding strip sub-electrode 201 of the plurality of strip sub-electrodes 201, that is, a side surface of the portion is inclined. Generally, an inclined angle of the side surface of the portion is about 60°. Those skilled in the art should understand that the groove 301 is formed by a patterning process (including an exposure process, a development process, an etching process, a stripping process, etc.) mostly. During the etching process, due to the process, the closer to the bottom surface of the groove, the lower the concentration of etching solution and the shorter the etching time, so that the groove formed by the etching process is inverted trapezoidal in shape. Based on this, for the above-described groove 301 formed by recessing overall in a region defined between each two adjacent strip sub-electrodes 201, as long as the opening of the groove 301 overlap corresponding side edges of two strip sub-electrodes of the plurality of strip sub-electrodes 201 adjacent to the groove 301.

The arrangement of the groove 301 in the above-mentioned insulating layer 30 will be further described below.

Referring to FIGS. 2 and 3a, the insulating layer 30 includes a gate insulating layer 31 and a protective layer 32 which are arranged in sequence, and the gate insulating layer 31 is located on a side of the protective layer 32 close to the base substrate 100. In this regard, those skilled in the art will understand that, in addition to the slit electrode 20 and the planar electrode 10, there are many other structures that are made in the manufacturing process of the array substrate, such as thin film transistors. Therefore, in actual manufacture, in order to simplify process, the insulating layer 30 disposed between the slit electrode 20 and the planar electrode 10 is generally shared with the insulating layer in the thin film transistors (that is, made by the same manufacturing process). For example, the gate insulating layer (GI) 31 and the protective layer (PVX) 32 can be used as the insulating layer 30.

Based on the above-described arrangement of the insulating layer 30, the arrangement of the grooves 301 can be as follows.

For example, referring to FIGS. 2 and 3a, in each of the sub-pixels P, the gate insulating layer 31 has a planar structure, and the protective layer 32 has hollow portions therein. A hollow portion includes sidewalls. As shown in FIG. 2, the hollow portion includes fourth sidewalls. The hollow portion and a portion of the gate insulating layer 31 corresponding to the hollow portion constitute the groove 301. In other words, the portion of the gate insulating layer 31 corresponding to the hollow portion constitutes the bottom of the groove 301, and sidewalls of the hollow portion in the protective layer 32 constitute sidewalls of the groove 301.

For another example, referring to FIGS. 2 and 4, in each of the sub-pixels P, the gate insulating layer 31 is a planar structure, and the groove 301 is located in the protective layer 32. In other words, sidewalls and a bottom of the groove 301 are located in the protective layer 32.

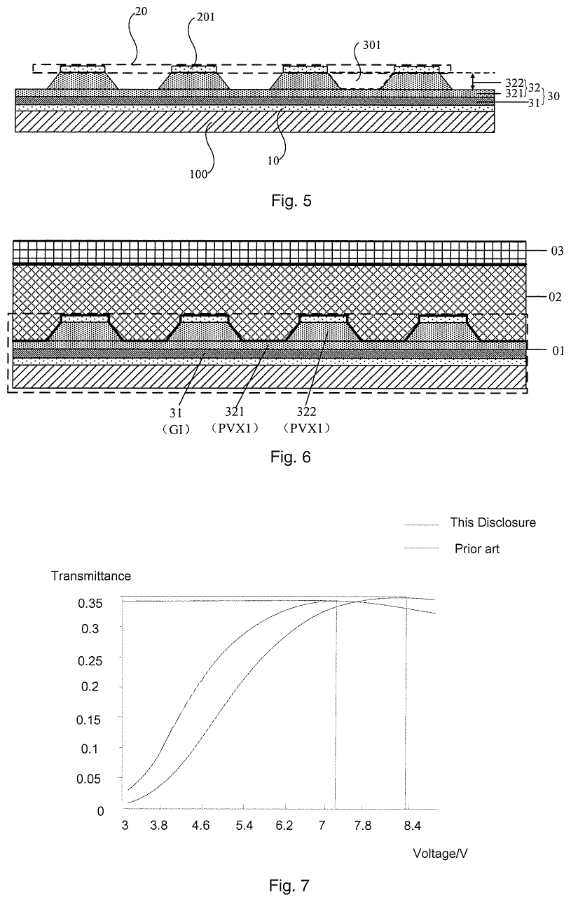

Of course, in a case where the groove 301 is located in the protective layer 32, optionally, as shown in FIG. 5, the protective layer 32 includes a first protective layer 321 and a second protective layer 322 that are disposed on the gate insulating layer 31 in sequence. The second protective layer 322 has hollow portions therein. A hollow portion and a portion of the first protective layer 321 corresponding to the hollow portion constitute the groove 301. In other words, the portion of the first protective layer 321 corresponding to the hollow portion constitutes the bottom of the groove 301, and sidewalls of the hollow portion in the second protective layer 322 constitute sidewalls of the groove 301.

Based on the above-described arrangement of the groove 301, a depth of the groove ranges from 0.4 μm to 0.7 μm.

Illustratively, if the depth of the groove is less than 0.4 μm, the thickness of a portion of the insulating layer 30 located between corresponding two adjacent strip sub-electrodes 201 of the plurality of strip sub-electrodes 201 is still larger, that is, the weakening effect of the insulating layer 30 on the electric field formed between the slit electrode 20 and the planar electrode 10 may not be significantly reduced. If the depth of the groove is greater than 0.7 μm, the thickness of the insulating layer 30 located between the slit electrode 20 and the planar electrode 10 is required to be sufficiently large. Therefore, considering that the manufacturing thickness of each film layer in the actual manufacturing of the array substrate and a setting concept of lighting and thinning, in some embodiments of the present disclosure, the depth of the groove is between 0.4 μm and 0.7 μm.

Of course, considering that the directly facing area between the slit electrode 20 and the planar electrode 10 is relatively large in the ADS type array substrate, the storage capacitance between the slit electrode 20 and the planar electrode 10 is larger than the storage capacitance that is actually required. For example, a storage capacitance required for normal display ranges from 300 pF to 500 pF, but the storage capacitance between the slit electrode 20 and the planar electrode 10 in the ADS type array substrate is up to 600 pF or more. Therefore, in order to properly reduce the storage capacitance, in some embodiments of the present disclosure, the depth of the groove 301 ranges from 0.4 μm to 0.7 μm. In a case where the groove 301 is located in the protective layer 32, as shown in FIGS. 4 and 5, a distance from the bottom of the groove 301 to a surface of the gate insulating layer 31 facing away from the base substrate 100 is set to a value from 0.15 μm to 0.25 μm (corresponding to that the thickness of the first protective layer 321 ranges from 0.15 μm to 0.25 μm for the array substrate shown in FIG. 5), to appropriately increase the distance between the slit electrode 20 and the planar electrode 10, thereby reducing the storage capacitance between the slit electrode 20 and the planar electrode 10, so as to achieve the capacitance required for the normal display.

Some embodiments of the present disclosure provide a display device, and the display device includes any of the array substrates described above. The display device including any of the array substrates has the same structures and beneficial effects as the array substrate provided by the above-mentioned embodiments. Since the above-mentioned embodiments have described the structures and beneficial effects of the array substrate in detail, which will not be repeated here.

It will be noted that the display device can be any product or component having a display function, such as a liquid crystal display, a liquid crystal television, a digital photo frame, a mobile phone or a tablet computer.

As shown in FIG. 6, the display device includes an array substrate 01, a color film substrate 03, and a liquid crystal layer 02 disposed between the array substrate 01 and the color film substrate 03. Of course, the display device further includes alignment layers PI located on both sides of the liquid crystal layer 02, and the like, which will not be described in detail here.

The relevant parameters, such as the storage capacitances, the operating voltages and the like, of the array substrate in FIG. 6 of the present disclosure and the array substrate in FIG. 1 achieved by actual measurement when the substrates are applied to the display devices respectively are further compared and described below.

Taking the array substrate 01 shown in FIG. 5 as an example (referring to the display device of FIG. 6), a thickness of the gate insulating layer (GI) 31 is 0.4 μm, a thickness of the first protective layer (PVX1) 321 is 0.2 μm, a thickness of the second protective layer (PVX2) 322 is 0.6 μm (i.e., the depth of the groove is 0.6μm), and an average thickness of the liquid crystal layer 02 is 3.55 μm.

Referring to FIG. 1, accordingly, the thickness of the gate insulating layer (GI) is 0.4 μm, a thickness of the protective layer (PVX) is 0.6 μm, and the thickness of the liquid crystal layer 02 is 3.55 μm.

Based on the above setting parameters, and by the actual measurement, the data is shown in the following table:

| Project | Embodiment of FIG. 1 | Embodiment of FIG. 6 |
|---|---|---|
| Storage capacitance | 100% | 87.3% |
| Transmittance | 100% | 98% |
| Operating voltage (V) | 8.4 | 7.2 |

It can be seen that the storage capacitance in the embodiment shown in FIG. 6 is 87.3%, which is equivalent to a reduction of 12.7% based on the storage capacitance and transmittance of 100% measured in the embodiment shown in FIG. 1. In combination with the above table and a relationship between the voltage and the transmittance in FIG. 7, it can be seen that a voltage corresponding to a maximum transmittance in the embodiment shown in FIG. 6 is about 7.2 V, while a voltage corresponding to a maximum transmittance in the embodiment shown in FIG. 1 is about 8.4V. In other words, the operating voltage (7.2 V) of the embodiment shown in FIG. 6 is significantly smaller than the operating voltage (8.4 V) in the embodiment shown in FIG. 1. Of course, it can be seen from the above table that the designing solution in the embodiment shown in FIG. 6 will reduce the transmittance of the display device relative to the embodiment shown in FIG. 1, but the reduction is not obvious and will have no actual impact on the display.

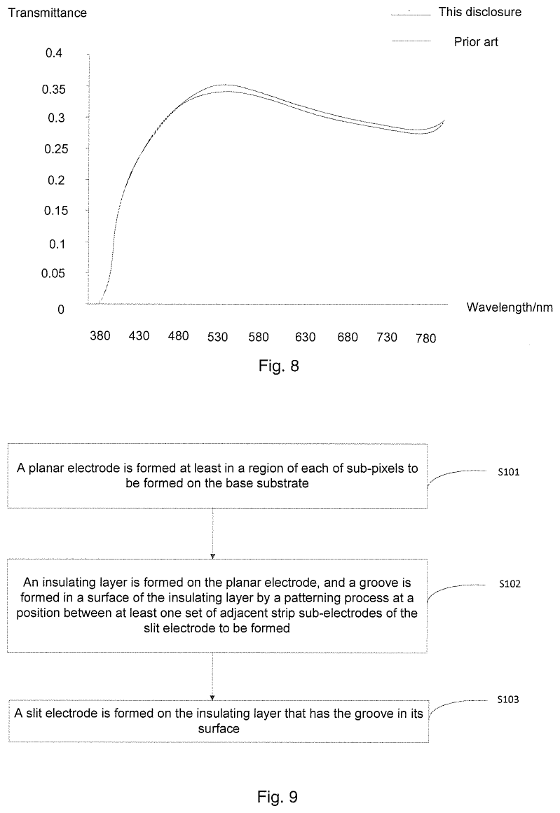

In addition, as shown in FIG. 8, a color temperature of the technical solution of the present disclosure is substantially consistent with a color temperature in the embodiment shown in FIG. 1. In other words, in FIG. 8, compared the solution of the present disclosure with the solution of the embodiment shown in FIG. 1, both of them have a substantially coincident curve of light wavelength and transmittance.

In summary, compared with the embodiment shown in FIG. 1, the solution provided by the embodiments of the present disclosure may reduce the operating voltage and the storage capacitance, without changing the color temperature.

Some embodiments of the present disclosure provide a manufacturing method of an array substrate. As shown in FIG. 9, the manufacturing method includes the following steps (combined with the diagram of the array substrate in FIGS. 2 and 3a).

In S101 (step 101), a planar electrode 10 is formed at least in a region of each of sub-pixels P to be formed on a base substrate 100.

In S102 (step 102), an insulating layer 30 is formed on the planar electrode 10, and a groove 301 is formed in a surface of the insulating layer 30 by a patterning process at a position between at least one set of adjacent strip sub-electrodes 201 in a plurality of adjacent strip sub-electrodes 201 of a slit electrode 20 to be formed.

The slit electrode 20 to be formed refers to a slit electrode 20 formed in a subsequent process.

In S103 (step 103), the slit electrode 20 is formed on the insulating layer 30 that has the groove 301 in its surface.

Based on this, in the array substrate made by the solution of the present disclosure, because in the surface of the insulating layer between the planar electrode and the slit electrode, the groove is provided at the position between adjacent strip sub-electrodes in the plurality of strip sub-electrodes, a thickness of a portion of the insulating layer 30 corresponding to the position between the adjacent strip sub-electrodes 201 of the plurality of strip sub-electrodes 201 is reduced. In this way, compared to the solution in the embodiment shown in FIG. 1 where the thickness of the entire insulating layer 30 is uniform, in the embodiments of the present disclosure, it is possible to ensure that the directly facing area between the slit electrode 20 and the planar electrode 10 is constant, that is, the storage capacitance is not increased, and on this basis, by reducing the thickness of the portion of the insulating layer 30 at the position between the adjacent strip sub-electrodes 201 in the plurality of strip sub-electrodes 201, the weakening effect of the insulating layer 30 on the electric field formed between the slit electrode 20 and the planar electrode 10 may be reduced. Therefore, the utilization of the electric field between the planar electrode 10 and the slit electrode 20 may be improved, thereby lowering the operating voltage, that is, as for a display device including the array substrate, power consumption may be reduced.

The above step S102, in which the insulating layer 30 is formed on the planar electrode 10, and the groove 301 is formed in a surface of the insulating layer 30 by a patterning process at a position between the at least one set of adjacent strip sub-electrodes 201 in the plurality of adjacent strip sub-electrodes 201 of the slit electrode 20 to be formed, will be further explained in detail.

The S102 may include the following steps (referring to FIG. 4).

In a first step, a gate insulating layer 31 is formed on the planar electrode 10.

In a second step, the protective layer 32 is formed on the gate insulating layer 31, and the groove 301 is formed in a surface of the protective layer 32 by a patterning process at a position between the at least one set of adjacent strip sub-electrodes 201 in the plurality of adjacent strip sub-electrodes 201 of the slit electrode 20 to be formed.

Of course, this S102 may include the following steps (referring to FIG. 3a).

In a first step, a gate insulating layer 31 is formed on the planar electrode 10.

In a second step, a protective layer 32 is formed on the gate insulating layer 31, and the hollow portion 301 is formed in a surface of the protective layer 32 by a patterning process at a position between the at least one set of adjacent strip sub-electrodes 201 in the plurality of adjacent strip sub-electrodes 201 of the slit electrode 20 to be formed. The hollow portion and a portion of the gate insulating layer corresponding to the hollow portion constitute the groove.

Alternatively, the S102 may include the following steps (referring to FIG. 5):

In a first step, a gate insulating layer 31 is formed on the planar electrode 10.

In a second step, a first protective layer 321 is formed on the gate insulating layer 31.

In a third step, a second protective layer 322 is formed on the first protective layer 321, and a hollow portion is formed in a surface of the second protective layer 322 by a patterning process at the position between the at least one set of adjacent strip sub-electrodes 201 in the plurality of adjacent strip sub-electrodes 201 of the slit electrode 20 to be formed. The hollow portion and a portion of the first protective layer 321 corresponding to the hollow portion constitute the groove 301.

In addition, in order to furthest reduce the weakening effect of the insulating layer 30 on the electric field formed between the slit electrode 20 and the planar electrode 10, in some embodiments of the present disclosure, the above S102 includes the following steps (referring to FIG. 3a).

The insulating layer 30 is formed on the planar electrode 10, and the groove 301 is formed in the surface of the insulating layer 30 by a patterning process at a position between every two adjacent strip sub-electrodes 201 in the plurality of adjacent strip sub-electrodes 201 of the slit electrode 20 to be formed.

It will be noted that, in the present disclosure, the patterning process includes a photolithography process, or includes a photolithography process and an etching process, and further includes other processes for forming a predetermined pattern, such as printing, inkjet, and the like. The photolithography process refers to a process of forming a pattern by using a photoresist, a mask, an exposure machine, or the like, including processes of film formation, exposure and development. A suitable patterning process may be selected in accordance with a structure formed in the present disclosure.

In addition, for other information related to the method for manufacturing the array substrate in the embodiments, reference may also be made to the specific description in the foregoing array substrate embodiment, which will not be repeated here.

The foregoing descriptions are merely some specific implementation manners of the present disclosure, but the protection scope of the present disclosure is not limited thereto, and the changes or replacements that any person skilled in the art can easily think of in the technical scope disclosed by the present disclosure should be within the protection scope of the present disclosure. Therefore, the protection scope of the present disclosure shall be subject to the protection scope of the claims.

1. An array substrate, comprising:
a slit electrode and a planar electrode disposed in each of sub-pixels on a base substrate, the planar electrode being disposed on a side of the slit electrode close to the base substrate, and the slit electrode comprising a plurality of strip sub-electrodes; and,
an insulating layer, in each of the sub-pixels, an disposed between the slit electrode and the planar electrode, wherein a surface of the insulating layer facing away from the base substrate is provided with a groove at a position between at least one set of adjacent strip sub-electrodes in the plurality of strip sub-electrodes.

2. The array substrate according to claim 1, wherein, the surface of the insulating layer facing away from the base substrate is provided with a groove at a position between every two adjacent strip sub-electrodes in the plurality of strip sub-electrodes.

3. The array substrate according to claim 2, wherein, the surface of the insulating layer facing away from the base substrate is integrally recessed in a defined region between every two adjacent strip sub-electrodes in the plurality of strip sub-electrodes to form the groove.

4. The array substrate according to claim 1, wherein the array substrate further comprises a dielectric layer located between the base substrate and the planar electrode, and the dielectric layer comprises a raised portion corresponding to a position of the groove.

5. The array substrate according to claim 1, wherein, the insulating layer comprises a gate insulating layer and a protective layer disposed in sequence, and the gate insulating layer is located on a side of the protective layer close to the base substrate;
in each of the sub-pixels, the gate insulating layer is a planar structure, and the protective layer has a hollow portion therein, wherein the hollow portion and a portion of the gate insulating layer corresponding to the hollow portion constitute the groove.

6. The array substrate according to claim 1, wherein, the insulating layer comprises a gate insulating layer and a protective layer disposed in sequence, and the gate insulating layer is located on a side of the protective layer close to the base substrate;
in each of the sub-pixels, the gate insulating layer is a planar structure, and the groove is located in the protective layer.

7. The array substrate according to claim 6, wherein, the protective layer comprises a first protective layer and a second protective layer which are disposed on the gate insulating layer in sequence, the second protective layer has a hollow portion therein, and the hollow portion and a portion of the first protective layer corresponding to the hollow portion constitute the groove.

8. The array substrate according to claim 1, wherein, a depth of the groove ranges from 0.4 μm to 0.7 μm.

9. The array substrate according to claim 6, wherein, a depth of the groove ranges from 0.4 μm to 0.7 μm, and a distance from a bottom of the groove to a surface of the gate insulating layer facing away from the base substrate ranges from 0.15 μm to 0.25 μm.

10. A display device, comprising the array substrate according to claim 1.

11. A manufacturing method of an array substrate, comprising:
forming a planar electrode at least in a region of each of sub-pixels to be formed on a base substrate;
forming an insulating layer on the planar electrode, and forming a groove in a surface of the insulating layer by a patterning process at a position between at least one set of adjacent strip sub-electrodes in a plurality of adjacent strip sub-electrodes of a slit electrode to be formed; and
forming a slit electrode on the insulating layer that has the groove in its surface.

12. The manufacturing method according to claim 11, wherein, forming the insulating layer on the planar electrode, and forming the groove in the surface of the insulating layer by the patterning process at the position between at least one set of adjacent strip sub-electrodes in a plurality of adjacent strip sub-electrodes of the slit electrode to be formed, comprises:
forming a gate insulating layer on the planar electrode; and
forming a protective layer on the gate insulating layer, and forming a groove in a surface of the protective layer by a patterning process at a position between the at least one set of adjacent strip sub-electrodes in the plurality of adjacent strip sub-electrodes of the slit electrode to be formed, or
forming a protective layer on the gate insulating layer, and forming a hollow portion in a surface of the protective layer by a patterning process at a position between the at least one set of adjacent strip sub-electrodes in the plurality of adjacent strip sub-electrodes of the slit electrode to be formed, wherein the hollow portion and a portion of the gate insulating layer corresponding to the hollow portion constitute the groove.

13. The manufacturing method according to claim 11, wherein, forming the insulating layer on the planar electrode, and forming the groove in the surface of the insulating layer by the patterning process at the position between at least one set of adjacent strip sub-electrodes in a plurality of adjacent strip sub-electrodes of the slit electrode to be formed, comprises:
forming a gate insulating layer on the planar electrode;
forming a first protective layer on the gate insulating layer; and
forming a second protective layer on the first protective layer, and forming a hollow portion in a surface of the second protective layer by a patterning process at a position between the at least one set of adjacent strip sub-electrodes in the plurality of adjacent strip sub-electrodes of the slit electrode to be formed, and the hollow portion and a portion of the first protective layer corresponding to the hollow portion constitute the groove.

14. The manufacturing method according to claim 11, wherein, forming the insulating layer on the planar electrode and forming the groove in the surface of the insulating layer by the patterning process at the position between at least one set of adjacent strip sub-electrodes in a plurality of adjacent strip sub-electrodes of the slit electrode to be formed, comprises:
forming an insulating layer on the planar electrode and forming a groove in a surface of the insulating layer by a patterning process at a position between every two adjacent strip sub-electrodes in the plurality of adjacent strip sub-electrodes of the slit electrode to be formed.
